(19) United States
(12) Patent Application Publication
(10) Pub. No.: US 2026/0211027 A1
(43) Pub. Date: Jul. 23, 2026

(54) Workstation-Based Modular Oven Assemblies for Component Testing and Methods of Using the Same

(71) Applicant: Adom Industries, Inc., Argyle, TX (US)

(72) Inventors: John Lauer, Argyle, TX (US); Adonis Lysandrou, Dallas, TX (US)

(21) Appl. No.: 19/456,433

(22) Filed: Jan. 22, 2026

Related U.S. Application Data
(60) Provisional application No. 63/747,983, filed on Jan. 22, 2025.

(51) Int. Cl. G01R 31/28

(52) U.S. Cl. CPC G01R 31/2862; G01R 31/2875; G01R 31/2877

(57) ABSTRACT

A workstation-based modular oven assembly for testing electronic components includes a modular oven mounted on a work surface. The modular oven includes a top portion and a bottom portion that form an oven interior when assembled. An oven aperture receives a test board having electronic components mounted on a first portion located within the oven interior and test connectors mounted on a second portion located outside the oven interior. A thermal conditioning system includes a blower and a heat exchanger having a heating side and a cooling side. The thermal conditioning system circulates heated or cooled air through the oven interior to subject the electronic components to controlled thermal conditions while maintaining electrical access to the electronic components through the test connectors.

### RELATED APPLICATION

This application claims the benefit of U.S. Provisional Patent Application 63/747,983 filed on Jan. 22, 2025, entitled “WORKSTATION-BASED MODULAR OVEN ASSEMBLIES FOR COMPONENT TESTING AND METHODS OF USING THE SAME,” which is incorporated herein by reference for all purposes.

### TECHNICAL FIELD

This application is directed, in general, to electronic chips, circuits, and assemblies, and more specifically to workstation-based modular oven assemblies for component testing and methods of using the same.

### BACKGROUND

The following discussion of the background is intended to facilitate an understanding of the present disclosure only. It should be appreciated that the discussion is not an acknowledgement or admission that any of the material referred to was part of the common general knowledge at the priority date of the application.

Printed circuit boards (PCBs) are commonly used in the manufacture of electronic devices. PCBs typically contain a number of components, which are mounted onto a board, that are electrically connected by conductive traces printed onto the board. Components of a PCB may be any known type of component. Often integrated circuits or microchips are components of a PCB. The microchips, which may perform any number of functions, include, for example, microprocessors, memory chips, analog chips, sensors, logic chips, etc, just to name a few.

Microchips typically require testing after being designed and manufactured to ensure reliability and longevity of the microchips in the electronic devices to which the microchips will be used. Various testing methods are established for performing such tests. Some tests require the microchips being subjected to repeated heating and cooling cycles. While devices and methods for performing microchip and PCB testing involving repeated heating and cooling cycles is known, improvements are desired.

### SUMMARY

In one embodiment, an apparatus for testing electronic components includes a modular oven mounted onto a worksurface of a workstation. The modular oven includes a top portion, a bottom portion, an air inlet, an air outlet, and an aperture. The apparatus includes a heater or cooler coupled to the workstation to provide heating or cooling. The apparatus includes a blower fluidly coupled to the workstation. When assembled, the top portion of the oven and the bottom portion of the oven form an oven interior. The aperture is shaped and configured to sandwich a test board between the top portion of the modular oven and the bottom portion of the modular oven. The air inlet portion and the air outlet portion provide fluid communication between the interior of the oven and an exterior of the oven. The blower is in fluid communication with the heater or cooler. The heater or cooler is in fluid communication with the air inlet portion, so that air that is heated or cooled by the heater or cooler may be blown by the blower into the oven interior through the inlet portion and out of the oven interior through the outlet portion.

In one embodiment, a workstation-based modular oven assembly for testing electronic components includes a workstation having a work surface. The assembly includes a modular oven coupled to the work surface. The modular oven includes a top portion and a bottom portion that form an oven interior when assembled. The assembly includes an oven aperture formed in the modular oven and configured to receive a test board having electronic components mounted on a first portion and test connectors mounted on a second portion. The test board is positioned so that the first portion is located within the oven interior and the second portion is located outside the oven interior. The assembly includes a thermal conditioning system comprising a blower, a heat exchanger having a heating side and a cooling side, and air circulation pathways connecting the blower and heat exchanger to the oven interior. The thermal conditioning system is configured to circulate heated or cooled air through the oven interior to subject the electronic components to controlled thermal conditions while maintaining electrical access to the electronic components through the test connectors.

In one embodiment, a method for testing electronic components includes the steps of inserting a first portion of a test board into an interior portion of a modular oven. The test board is a printed circuit board having a plurality of electronic components coupled to the first portion of the test board. A second portion of the test board includes a plurality of test connectors and the second portion is not inserted into the interior portion of the modular oven. Each test connector is electrically coupled to one of the plurality of electronic components. The modular oven includes a top portion and a bottom portion and the test board is sandwiched between the top portion and the bottom portion of the modular oven. The method includes heating or cooling the plurality of electronic components by blowing heated or cooled air into the interior of the modular oven through an air inlet. The air inlet is in fluid communication with the interior of the modular oven and is in fluid communication with a heat exchanger. The heated or cooled air is heated or cooled in the heat exchanger prior to entering the interior of the modular oven. The heat exchanger is in fluid communication with a blower for blowing heated or cooled air into the interior of the modular oven through an air inlet. The method includes performing a component test on at least one of the components of the plurality of components without removing the first portion of the test board from the interior of the modular oven. The component test is performed by supplying an electrical current to the component to be tested through the test connectors that are electrically coupled to the component to be tested.

Other embodiments are disclosed.

### DESCRIPTION OF THE DRAWINGS

Illustrative embodiments of the present disclosure are described in detail below with reference to the attached drawing figures, which are incorporated by reference herein and wherein:

FIG. 1 is a schematic, perspective view of an illustrative embodiment of a portion of an apparatus and an oven for testing electronic components;

FIG. 2 is a schematic, perspective view of an illustrative embodiment of a portion of an apparatus and an oven for testing electronic components;

FIG. 3 is a schematic, perspective view of an illustrative embodiment of a portion of an apparatus and an oven for testing electronic components;

FIG. 4 is a schematic, perspective view of an illustrative embodiment of a bottom portion of an oven;

FIG. 5 is a schematic, perspective view of an illustrative embodiment of a bottom portion of an oven;

FIG. 6 is a schematic, perspective view of an illustrative embodiment of a top portion of an oven;

FIG. 7 is a schematic, perspective view of an illustrative embodiment of a top portion of an oven;

FIG. 8 is a schematic, perspective view of an illustrative embodiment of a portion of a test board for use in an oven;

FIG. 9 is a schematic, perspective view of an illustrative embodiment of a portion of an apparatus and an oven for testing electronic components;

FIG. 10 is a schematic, perspective view of an illustrative embodiment of a portion of an apparatus and an oven for testing electronic components;

FIG. 11 is a schematic, perspective view of an illustrative embodiment of a portion of an apparatus and an oven for testing electronic components;

FIG. 12 is a schematic, perspective view of an illustrative embodiment of a portion of an apparatus and an oven for testing electronic components; and

FIG. 13 is a flow chart of an illustrative embodiment of a method for testing electronic components using the modular oven assembly.

### DETAILED DESCRIPTION

In the following detailed description of the preferred embodiments, reference is made to the accompanying drawings that form a part hereof, and in which is shown, by way of illustration, specific embodiments in which the disclosure may be practiced. These embodiments are described in sufficient detail to enable those skilled in the art to practice the disclosure, and it is understood that other embodiments may be utilized, and that logical structural, mechanical, electrical, and chemical changes may be made without departing from the spirit or scope of the disclosure. To avoid detail not necessary to enable those skilled in the art to practice the disclosure, the description may omit certain information known to those skilled in the art. The following detailed description is, therefore, not to be taken in a limiting sense, and the scope of the present disclosure is defined only by the claims. Unless otherwise indicated, as used throughout this document, “or” does not require mutual exclusivity.

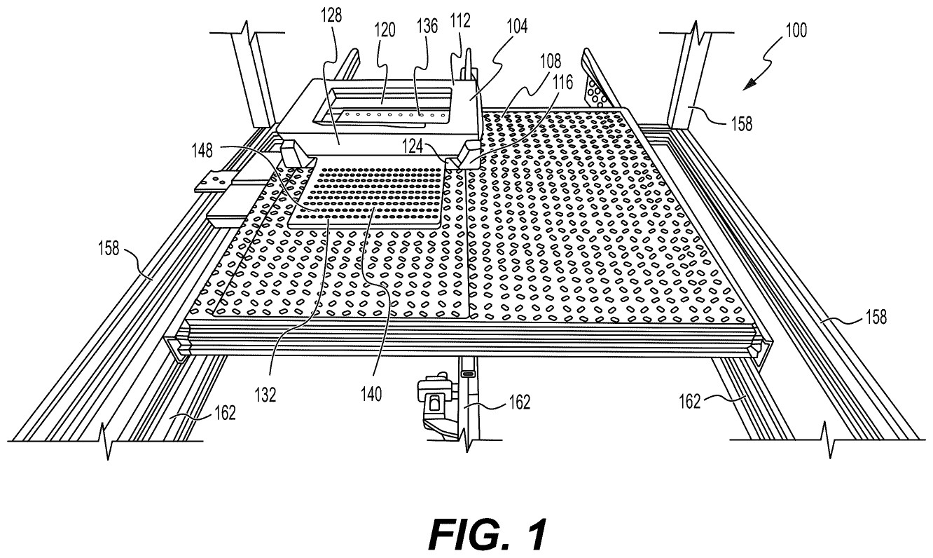

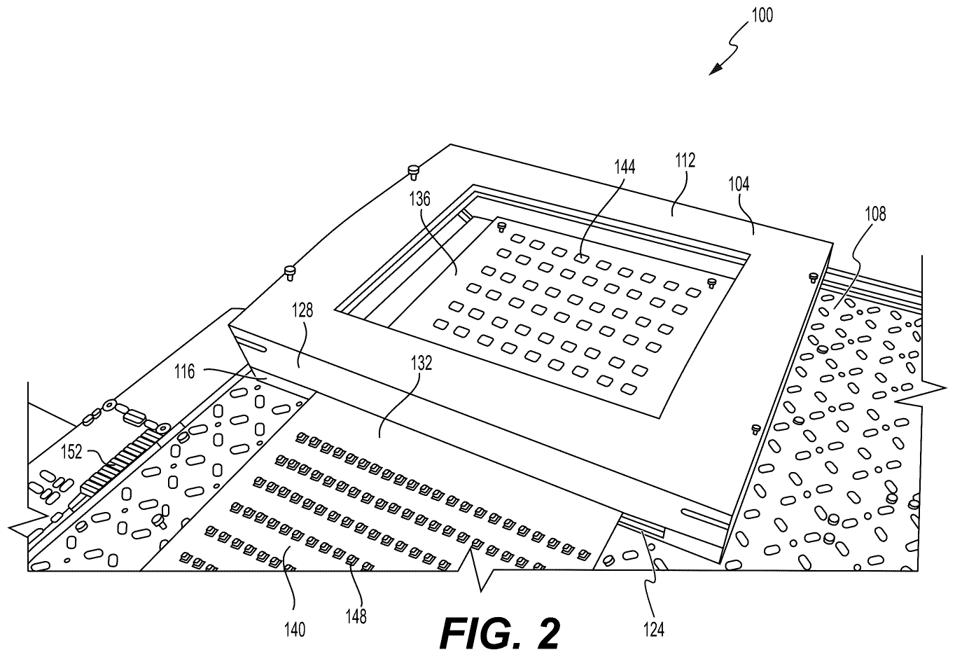

Referring now to FIGS. 1-3, and primarily to FIGS. 1 and 2, an illustrative embodiment of an electronic component workstation 100 will be described. The workstation 100 includes a modular oven 104 coupled to a work surface 108. The modular oven 104 includes a top portion 112 and a bottom portion 116. The bottom portion 116 is coupled to the work surface 108 to hold the oven 104 in place on the work surface 108. The top portion 112 of the oven 104 is placed onto the bottom portion 116, so that the top portion 112 and bottom portion 116 form an oven interior 120. The oven interior 120 is the portion of the oven 104 that is heated or cooled as further described below.

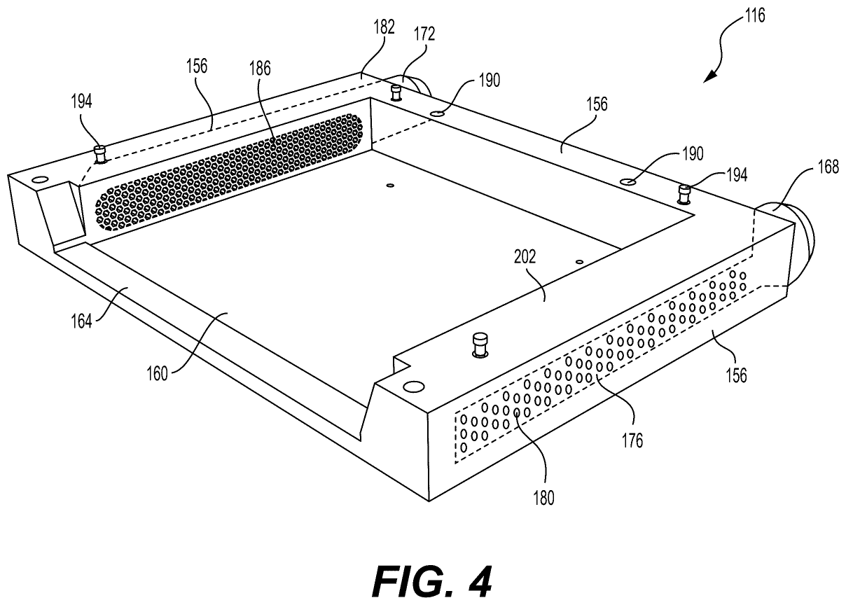

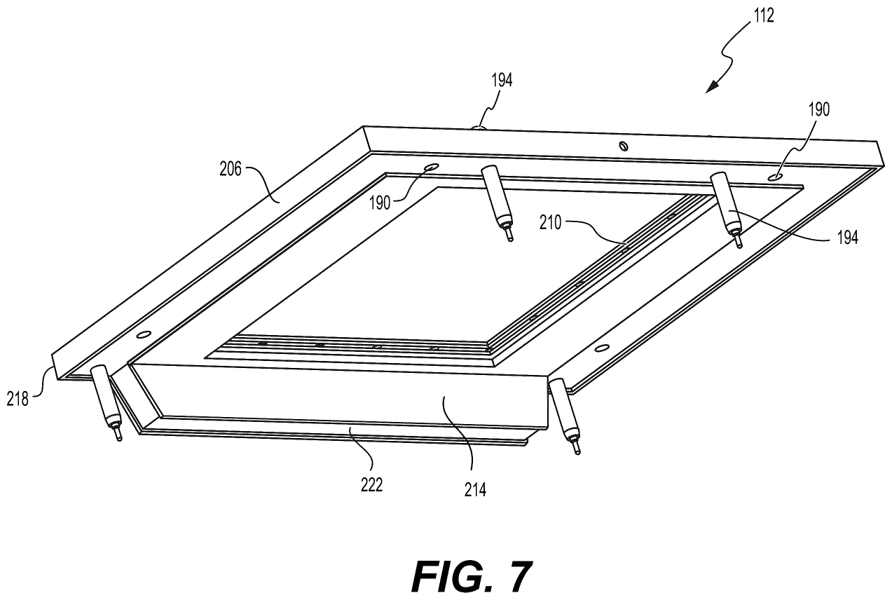

The oven 104 also includes an oven aperture 124 formed along a side wall 128 of the oven 104. The oven aperture 124 is sized and configured to receive a test board 132, so that when the top portion 112 of the oven 104 is placed onto the bottom portion 116 of the oven 104, the test board 132 is located at least partially within the aperture 124 and is sandwiched between the top portion 112 and the bottom portion 116. The sandwiching of the test board 132 by the top portion 112 and the bottom portion 116 forms a seal to substantially prevent or at least reduce air flow or thermal transfer through the aperture 124. The top portion 112 or bottom portion 116 may include a seal to assist in reducing air flow or thermal transfer through aperture 124. The aperture 124 may be formed by a cutout in the top portion 112 or the bottom portion 116, or by cutouts in both the top portion 112 and the bottom portion 116. A gasket may be formed out of a silicone rubber sponge and positioned along the aperture 124 as well as the contact faces between the top portion 112, exterior walls 156 (FIG. 4), and a bottom portion aperture 164 (FIG. 4) and bottom portion 116 of the oven with lower edge 222 (FIG. 7) to prevent thermal leakage throughout a thermal cycle without significant off gassing. In some embodiments, the gasket has a thickness of 2 mm. In some embodiments, the gasket is made from a lightweight silicone rubber sponge which is used (0.3 g/cm\hat{ }3) for compressibility and to minimize weight.

In addition to the silicone rubber sponge gasket described above, various other sealing options may be employed to enhance thermal isolation and prevent air leakage. O-ring seals may be positioned in grooves machined into the contact surfaces between the top portion 112 and bottom portion 116. The O-rings may be formed from materials such as nitrile rubber (NBR), fluorocarbon rubber (FKM), or perfluoroelastomer (FFKM) depending on the temperature requirements of the application. Compression seals may be utilized, where the sealing force is generated by mechanical compression of the gasket material between mating surfaces. Spring-loaded seals may be incorporated to maintain consistent sealing pressure even when thermal expansion or contraction occurs during temperature cycling. Metallic seals, such as those formed from soft metals like copper or aluminum, may be employed for high-temperature applications where elastomeric materials may degrade. Labyrinth seals may be machined into the oven components to create a tortuous path that restricts air flow without requiring contact between sealing surfaces. Magnetic seals utilizing permanent magnets embedded in flexible sealing material may provide consistent sealing force while allowing for easy assembly and disassembly of the oven components. Inflatable seals that can be pressurized with air or inert gas may be used to create variable sealing force depending on the operating conditions. The sealing system may incorporate multiple sealing technologies in combination, such as a primary O-ring seal with a secondary labyrinth seal to provide redundant sealing capability.

The test board 132 has a first portion 136 and a second portion 140. When a test is performed (as more fully described below), the first portion 136 of the test board 132 is located within the oven interior 120 and the second portion 140 of the test board 132 is located outside of the oven interior 120.

The configuration of having the first portion 136 of the test board 132 inside the oven interior 120 while the second portion 140 remains outside provides for the ability to interact with or operate electronic components 144 that are being tested while the electronic components 144 are still located in the oven interior 120 and without the needs to open the oven 104 for electronic component testing. The first portion 136, which contains the electronic components 144 being tested, is subjected to the controlled thermal environment within the oven 104, allowing the components to experience the desired heating, cooling, or thermal cycling conditions. Meanwhile, the second portion 140, which contains the test connectors 148, remains at ambient temperature outside the oven interior 120. This arrangement allows electrical access to the electronic components 144 during thermal testing without exposing the test connectors 148 to potentially damaging temperature extremes. The test connectors 148 provide electrical pathways to the electronic components 144 through PCB traces within the test board 132, enabling real-time monitoring and testing of component functionality while the components are under thermal stress. This configuration eliminates the need to remove components from the thermal environment to perform electrical tests, thereby maintaining continuous thermal conditions and providing more accurate test results that reflect real-world operating conditions where electronic components must function reliably across varying temperature ranges.

The plurality of electronic components 144 (FIG. 2) are coupled to the first portion 136 of the test board 132, so when a test is performed, the electronic components 144 are subjected to heating, cooling, or cycles of heating and cooling.

A plurality of test connectors 148 are coupled to the second portion 140 of the test board 132, so when a test is performed, the test connectors 148 are not subjected to heating, cooling, or cycles of heating and cooling, as more fully described below. That is, the test connectors 148 are not in the oven interior 120.

The test board 132 is a printed circuit board (PCB), and each of the test connectors 148 are coupled to particular electronic components 144 so that particular test connectors 148 that are electrically coupled to a particular electronic component 144 may be used to run operations and other tests on the electronic component 144.

The test board 132 is a printed circuit board (PCB), and each of the test connectors 148 are coupled to particular electronic components 144 so that particular test connectors 148 that are electrically coupled to a particular electronic component 144 may be used to run operations and other tests on the electronic component 144. The PCB is fabricated using standard printed circuit board manufacturing processes, beginning with a substrate material such as fiberglass-reinforced epoxy resin (FR-4) or other suitable dielectric material. Conductive traces are formed on the substrate using copper layers that are patterned through photolithographic processes, etching, and plating techniques. The PCB includes multiple layers of conductive traces separated by insulating layers, allowing for complex routing of electrical connections between components. Electronic components 144 are mounted to the first portion 136 of the PCB using surface mount technology (SMT) or through-hole mounting techniques. For surface mount components, solder paste is applied to designated pads on the PCB surface, the electronic components 144 are placed onto the solder paste using pick-and-place equipment, and the assembly is heated in a reflow oven to form permanent solder joints. Through-hole components are inserted into plated holes in the PCB and soldered on the opposite side. Test connectors 148 are mounted to the second portion 140 of the PCB using similar mounting techniques. Each electronic component 144 is electrically coupled to a corresponding test connector 148 through conductive traces that are routed within the PCB layers. The conductive traces form electrical pathways that connect specific pins or terminals of each electronic component 144 to designated pins of the corresponding test connector 148.

For example, a memory chip mounted as electronic component 144 may have data input/output pins, address pins, control pins, and power pins that are each connected through separate conductive traces to corresponding pins of test connector 148. A generic example of how a memory module (electronic component 144) may be tested while subjected to thermal cycling within the oven 104 illustrates the practical application of the workstation 100. The memory module may be mounted on the first portion 136 of the test board 132 and includes various pins for data transfer, address specification, control signals, and power supply. Each of these pins is connected through conductive traces within the PCB to corresponding pins of test connector 148 located on the second portion 140 of the test board 132. During thermal testing, the memory module undergoes temperature cycling while electrical tests are performed through the test connector 148. Write and read operations may be executed by applying appropriate signals through the test connector 148. The testing may include various stress patterns to verify data integrity across the temperature range. Power consumption measurements may be taken by monitoring current draw through the power supply pins during different operational modes including active, standby, and self-refresh states.

The routing of the traces is designed to maintain signal integrity and minimize electrical interference between different signal paths. The PCB design may include ground planes and power planes to provide stable electrical reference and power distribution to the electronic components 144 and test connectors 148.

The workstation 100 may include additional connectors 152 for providing functionality or power to the test board 132. For example, additional connectors 152 may include a DC voltage input, a ground, a network connection, data transfer connections, etc., and the like. The additional connectors 152 may be coupled to components of the test board 132 or workstation 100 by, for example, jumper wires to provide the desired additional functionality or power.

The workstation 100 may include additional connectors 152 for providing functionality or power to the test board 132. For example, additional connectors 152 may include a DC voltage input, a ground, a network connection, data transfer connections, etc., and the like. The additional connectors 152 may be coupled to components of the test board 132 or workstation 100 by, for example, jumper wires to provide the desired additional functionality or power. The additional connectors 152 serve multiple purposes in supporting the operation of the workstation 100 and enabling comprehensive testing of electronic components 144.

Power supply connectors provide regulated DC voltages at various levels such as 3.3V, 5V, 12V, and other voltages required by different electronic components 144 during testing. Ground connections establish electrical reference points and provide return paths for electrical currents, ensuring proper operation of the electronic components 144 and maintaining signal integrity throughout the test board 132. Network connections enable communication between the workstation 100 and external systems, allowing for remote monitoring, data logging, and automated test control. Data transfer connections facilitate high-speed communication protocols such as USB, Ethernet, serial communication interfaces, and other digital communication standards that may be required for testing specific types of electronic components 144. Clock signal connections provide timing references for synchronous electronic components 144 that require precise timing signals for proper operation. Control signal connections enable the workstation 100 to send command signals to electronic components 144 for initiating specific operational modes or test sequences. Analog signal connections support testing of electronic components 144 that process analog signals, providing signal generation and measurement capabilities. The additional connectors 152 may be implemented using standard connector types such as banana plugs, BNC connectors, D-sub connectors, or custom connector configurations depending on the specific requirements of the testing application. The flexibility provided by the additional connectors 152 allows the workstation 100 to be adapted for testing a wide variety of electronic components 144 with different interface requirements and operational characteristics.

The additional connectors 152 described above represent various options that may be implemented depending on the specific testing requirements and the type of electronic components 144 being tested. Not all of the connector types described may be necessary for every testing application, and the selection of which connectors to include depends on the operational characteristics and interface requirements of the particular electronic components 144 under test. Some testing scenarios may require only basic power and ground connections, while others may need comprehensive communication interfaces, analog signal capabilities, and specialized control signals. The modular design of the workstation 100 allows for customization of the additional connectors 152 to match the specific needs of different electronic component types, ensuring that the workstation 100 can accommodate a wide range of testing applications. The flexibility to select and configure appropriate additional connectors 152 enables the workstation 100 to operate effectively with whatever type of electronic component 144 is being tested, whether the components require simple DC power supplies, complex digital communication protocols, precise analog signal generation, or specialized control and monitoring capabilities.

Two illustrative test examples demonstrate the practical application of the workstation 100 for testing electronic components 144 under thermal conditions. In a first test example, high temperature gate bias testing may be performed on semiconductor devices such as power transistors or integrated circuits. The electronic components 144 are mounted on the first portion 136 of the test board 132 and subjected to elevated temperatures within the oven interior 120 while electrical bias voltages are applied through the test connectors 148. The test connectors 148 provide electrical pathways to apply gate voltages, drain voltages, and source connections to the semiconductor devices while monitoring leakage currents and threshold voltage shifts that may occur due to thermal stress. Temperature cycling between ambient and elevated temperatures allows for accelerated aging studies to predict long-term reliability of the semiconductor devices under operational conditions. In a second test example, temperature cycle testing may be performed on memory modules or microprocessors to evaluate thermal fatigue resistance. The electronic components 144 undergo repeated thermal cycling between low and high temperature extremes within the oven interior 120 while functional tests are executed through the test connectors 148. During the thermal cycling, read and write operations are performed on memory devices to verify data integrity, or computational tasks are executed on microprocessors to ensure continued functionality. The additional connectors 152 may provide network connections for automated test control and data logging, power supply connections for various voltage levels required by the components, and clock signal connections for synchronous operation of the electronic components 144 during the thermal stress testing.

The test examples described above are illustrative of the types of testing that may be performed using the workstation 100 but are not intended to be limiting. The workstation 100 and modular oven 104 may be used to test any type of electronic component 144 that requires evaluation under controlled thermal conditions. The flexibility of the system allows for testing of a wide variety of electronic components including but not limited to microprocessors, memory devices, analog integrated circuits, digital signal processors, power management circuits, radio frequency components, sensors, actuators, discrete semiconductor devices, and any other electronic components that may benefit from thermal testing. The modular design of the workstation 100, with its configurable additional connectors 152 and adaptable test board 132 configuration, enables the system to accommodate the diverse interface requirements, power specifications, and operational characteristics of virtually any electronic component type. The thermal testing capabilities of the oven 104, combined with the electrical access provided through the test connectors 148, allow for comprehensive evaluation of component performance, reliability, and functionality across the full range of operating temperatures that the components may encounter in their intended applications.

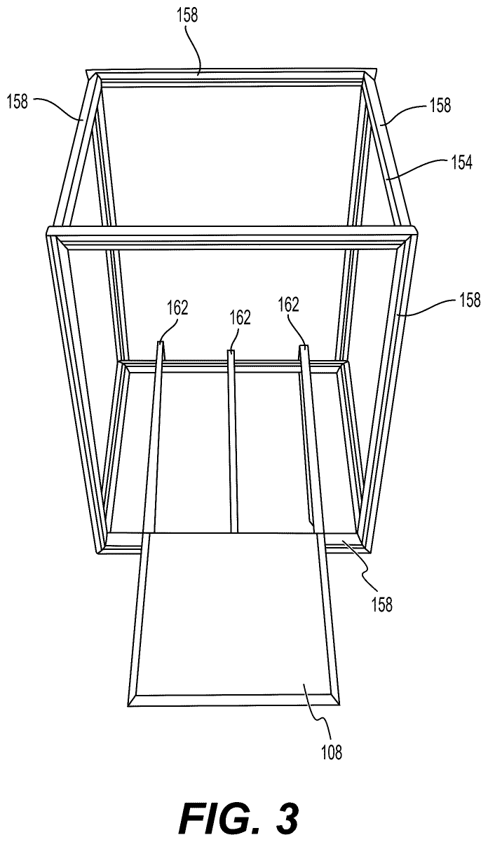

Still referring generally to FIGS. 1-3, and primarily to FIG. 3, other illustrative aspects of the workstation 100 will be discussed. As discussed above, the work surface 108 is the primary working surface of the workstation 100. The work surface 108 may be coupled to a scaffolding support 154 to facilitate use of the work surface 108. The scaffolding support 154 may include a plurality of support arms 158 coupled to each other to form the framework of the scaffolding support 154. A plurality of rails 162 may be coupled to at least some of the support arms 158 to form a base for the work surface 108. The rails 162 may be coupled to the work surface 108 in a manner that allows for the work surface 108 to slide along the rails 162 (e.g., wheel and rail connections or sliding connections). When the work surface 108 is coupled in such a manner, this allows for an operator to slide out the work surface 108 to facilitate placement of components on or around the work surface 108 or the workstation 100. This may be done manually or robotically.

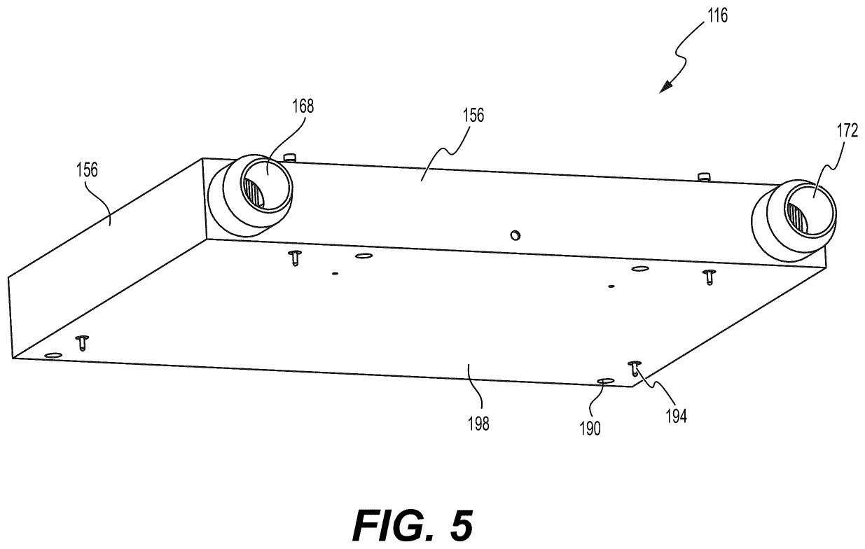

Referring now primarily to FIGS. 4-7, the bottom portion 116 and top portion 112 of the oven 104 will be discussed for one illustrative embodiment. FIGS. 4 and 5 present two different perspective views of an illustrative embodiment of the bottom portion 116 of the oven 104. The bottom portion 116 includes three exterior walls 156 located along outer edges of a bottom plate 160. A bottom portion aperture 164, is formed along the outer edge of a bottom plate 160 that does not have an exterior wall 156. The bottom portion aperture 164 forms at least part of the oven aperture 124 when the bottom portion 116 and the top portion 112 are coupled together. The inner cavity 120 is at least partially formed between the exterior walls 156 of the bottom portion 116 of the oven 104. In some embodiments, a void exists formed by the bottom surface 198, exterior walls 156, and bottom plate 160 in which a minimum of 2.5 mm air gap is maintained between the inner and outer walls and a vacuum may be pulled from this enclosed space for low profile and lightweight thermal insulation.

The bottom portion 116 includes an air inlet 168 and an air outlet 172. While “air” is used herein, it should be understood that “air” includes any gas or gaseous mixture suitable for heating and cooling in the oven. Each of the air inlet 168 and the air outlet 172 provide fluid communication between the exterior of the oven 104 and the oven interior 120. Air (or other gas) is able to flow into the air inlet 168 through an inlet flow chamber 176 and then through a plurality of inlet vents 180 to reach the oven interior 120. Likewise, air (or other gas) may flow out of the oven interior 120. To exit the oven interior 120, air (or other gas) may flow through a plurality of outlet vents 186 into an outlet flow chamber or manifold 182. From there air (or other gas) may flow to the exterior of the oven 104 by passing through the air outlet 172. The inlet flow chamber 176 and outlet flow chamber 182 are shown by broken line in FIG. 4. The inlet flow chamber 176 and outlet flow chamber 182 contain two sets of identical (but mirrored) air flow veins. The air passes through the inlet flow chamber 176 and is first partitioned by vertical fins for the purposes of pressure balancing the incoming air. The air is then segmented through hexagonal veins which may allow the incoming air to behave laminarly within the interior of the oven 120.

In such a manner, a circulation path is formed wherein heated or cooled air may be circulated through the interior 120 of the oven 104, thereby heating or cooling electronic components 144 (FIGS. 1 and 2) located within the oven interior 120 of the oven 104.

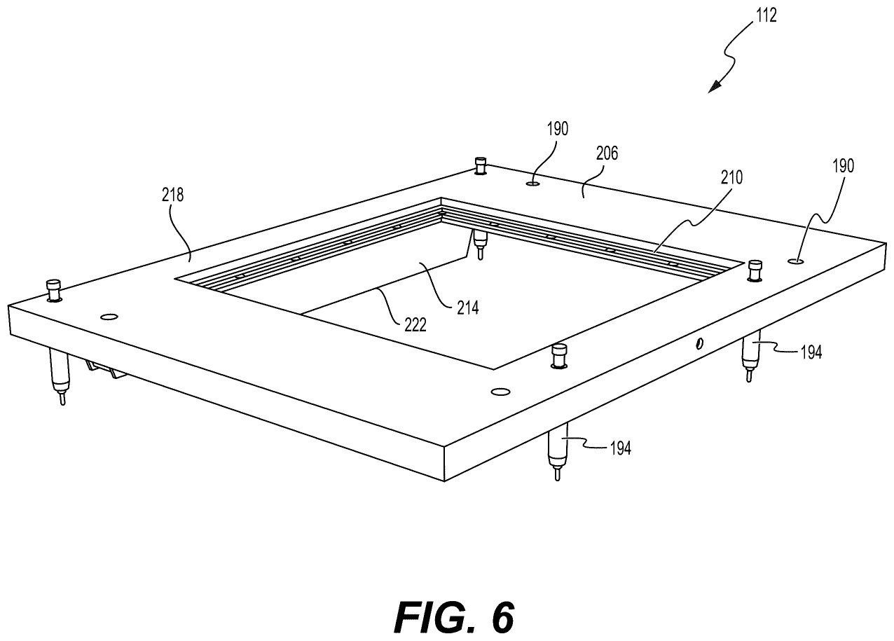

The bottom portion 116 may also include mating pins 194 and mating holes 190, each of which may be used to couple the bottom portion 116 to other components of the workstation 100. For example, mating holes 190 located on a bottom surface 198 of the bottom portion 116 may be sized and configured to receive corresponding mating pins 194 located on the work surface 108 to facilitate coupling of the bottom portion 116 to the work surface 108. Likewise, mating pins 194 located on an upper surface 202 of the bottom portion 116 may be sized and configured to be inserted into corresponding mating holes 190 (FIG. 6) located on the top portion 112 of the oven 104.

Referring now primarily to FIGS. 6 and 7, the top portion 112 of an illustrative embodiment of the oven 104 will be further discussed. The top portion 112 of the oven 104 has a top plate 206. A viewing aperture 210 is formed within the top plate 206. The viewing aperture 210 is filled with at least one pane of transparent material such as glass or plastic and provides the ability to view the electronic components 144 (FIG. 2) while the oven 104 is in use. A vacuum may be pulled between two panes of transparent material disposed within the viewing aperture 210 to thermally insulate the interior 120. In some embodiments, the top plate 206 is solid and does not include the viewing aperture 210. In some embodiments, an inner cavity is formed, analogous to the bottom portion 116, between the lower edge 222, front wall 214, top plate 206, in which a minimum of 2.5 mm gap is maintained and a vacuum may be pulled for thermal insulation.

The top portion 112 has front wall 214 extending substantially perpendicular from the surface of the top plate 206 at a front edge 218 of the top portion 112. The front wall 214 is sized and configured to fit substantially within the bottom portion aperture 164 (FIGS. 5 and 6) when assembled so that the front wall 214 and the bottom portion aperture 164 form the aperture 124 of the oven 104. The lower edge 222 of the front wall 214 may include a gasket or other seal for sealing to the test board 132 (FIG. 2) when in use. A gasket may be applied throughout an entire track that wraps around the top portion of the oven or around the entire top.

The top portion may also include mating pins 194 and mating holes 190. The mating pins 194 and mating holes 190 of the top portion 112 are used in a manner analogous to that described in relation to the mating pins 194 and mating holes 190 of the bottom portion 116 to align, stack, couple, or secure components.

The top portion 112 and the bottom portion 116 may be formed from any material that provides sufficient structure to form the oven 104 and that is capable of withstanding or operating within the expected temperature ranges that the oven 104 will be used in. In one embodiment, the top portion 112 and the bottom portion 116 are, at least partially, formed from stainless steel, and in some embodiments is 316L stainless steel with a silicone rubber sponge gasket.

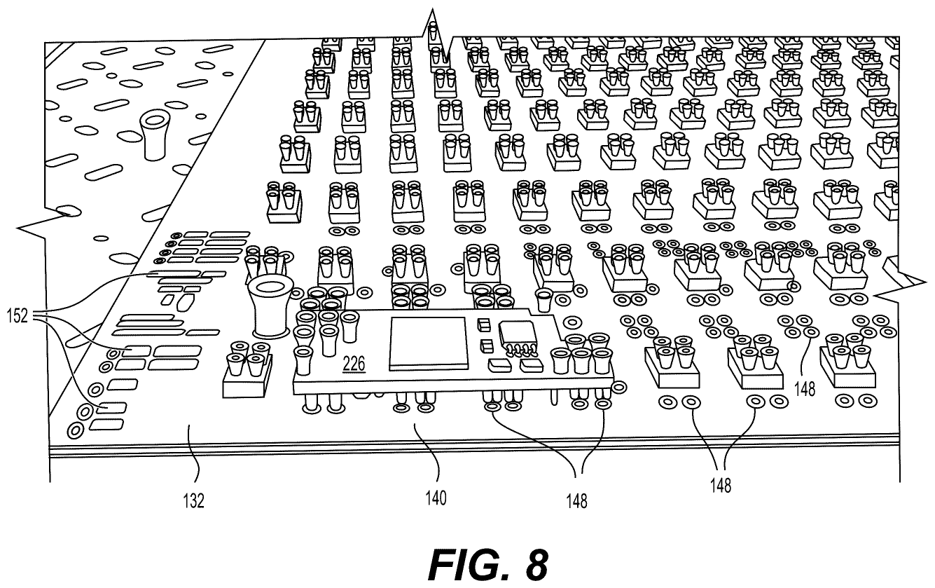

Now referring primarily to FIG. 8, the second portion 140 and test connectors 148 of an illustrative test board 132 will be discussed. As discussed in relation to FIGS. 1 and 2, the second portion 140 of the test board 132 is not located within the interior 120 of the oven 104 during testing, heating, or cooling operations. Since the second portion 140 is not located within the interior 120 of the oven 104, the second portion 140 may be used to access functionality of the electronic components 144 that are located within the interior 120 of the oven 104.

Access to such functionality occurs through test connectors 148. Each of the electronic components 144 to be tested has a corresponding set of test connectors 148. Each test connector 148 may be electrically coupled to a terminal or prong of the electronic component 144 to which the test connector 148 corresponds. Electrical connections between test connectors 148 and electronic components 144 (FIG. 2) are made through PCB traces within the test board 132.

Therefore, the test connectors 148 allow for the operation or function of the electronic components 144 that are being tested while the electronic components 144 are heated or cooled or cycled within the oven 104. For example, read and write operations of a memory chip (which in the example is the electronic component 144) may be tested at different temperatures by inputting the required signal to the memory chip through the test connectors 148. In some embodiments, a testing assembly 226 may be used to cycle the electronic components 144 through various tests. The testing assembly 226 may be configured to connect to the test connectors 148 and execute test sequences on the electronic components 144 while the electronic components 144 are subjected to thermal conditioning

The testing assembly 226 may serve as an external test control and interface system that can connect to the test connectors 148 to provide comprehensive testing capabilities for the electronic components 144 under thermal stress. The testing assembly 226 may be used to cycle the electronic components 144 through various tests. The testing assembly 226 may be another PCB that can include the components necessary to test the electronic components 144 and that connects to the test connectors 148 through pins or other couplings designed to mate with the test connectors 148. The testing assembly 226 may include signal generation circuits, measurement circuits, control logic, and data acquisition systems that can execute complex test sequences on the electronic components 144 while the components remain within the controlled thermal environment of the oven 104. The testing assembly 226 may include programmable power supplies that can provide precise voltage and current levels required by different types of electronic components 144, signal generators that can produce test patterns, waveforms, and timing signals, measurement instruments such as digital multimeters, oscilloscopes, and spectrum analyzers for monitoring component responses, and automated test equipment (ATE) controllers that can execute predefined test sequences and collect performance data. The modular design of the testing assembly 226 may allow for customization based on the specific requirements of the electronic components 144 being tested, with interchangeable test modules that can be configured for different component types and test protocols.

Example applications of the testing assembly 226 may demonstrate the versatility of the system for different types of electronic component testing. For memory device testing, the testing assembly 226 may include memory controllers that can execute read and write operations, pattern generators that can create specific data patterns for stress testing, and error detection circuits that can monitor data integrity during thermal cycling. The testing assembly 226 may perform comprehensive memory tests including data retention tests where specific patterns can be written to memory locations and verified after extended periods at elevated temperatures, endurance tests that can repeatedly write and erase memory cells while monitoring for wear-out mechanisms, and functional tests that can verify proper operation of memory interface signals and timing parameters across the full temperature range. For microprocessor testing, the testing assembly 226 may include instruction generators that can execute computational tasks, performance monitors that can measure processing speed and power consumption, and diagnostic systems that can verify proper operation of internal processor functions. The testing assembly 226 may execute benchmark programs, stress test algorithms, and functional verification sequences while the microprocessor undergoes thermal cycling, providing comprehensive evaluation of processor reliability and performance under thermal stress. For analog integrated circuit testing, the testing assembly 226 may include precision signal sources, high-resolution measurement systems, and specialized test circuits for evaluating analog parameters such as gain, bandwidth, noise, and linearity across temperature variations. The testing assembly 226 may enable automated execution of complex test sequences that would be difficult or impossible to perform manually, while providing detailed data logging and analysis capabilities for comprehensive component characterization under thermal stress conditions.

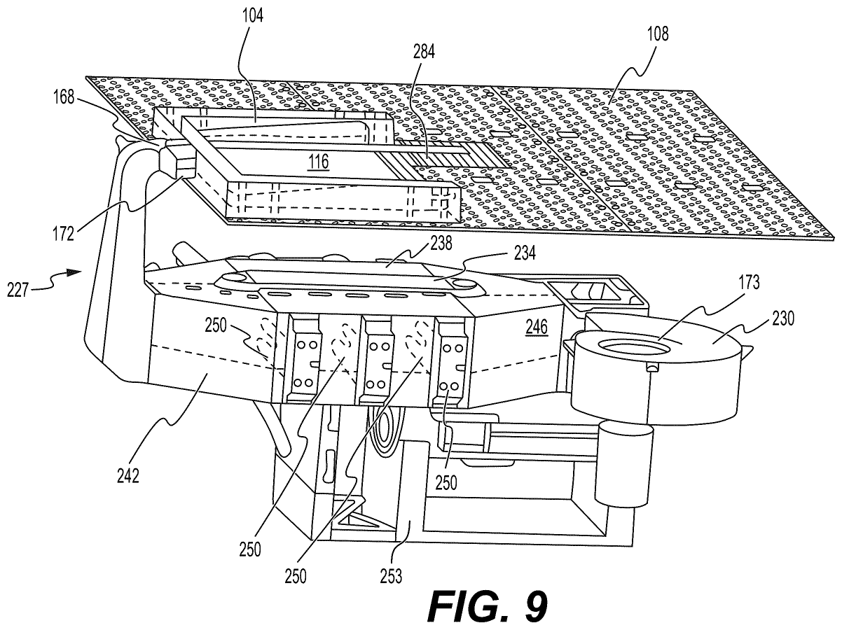

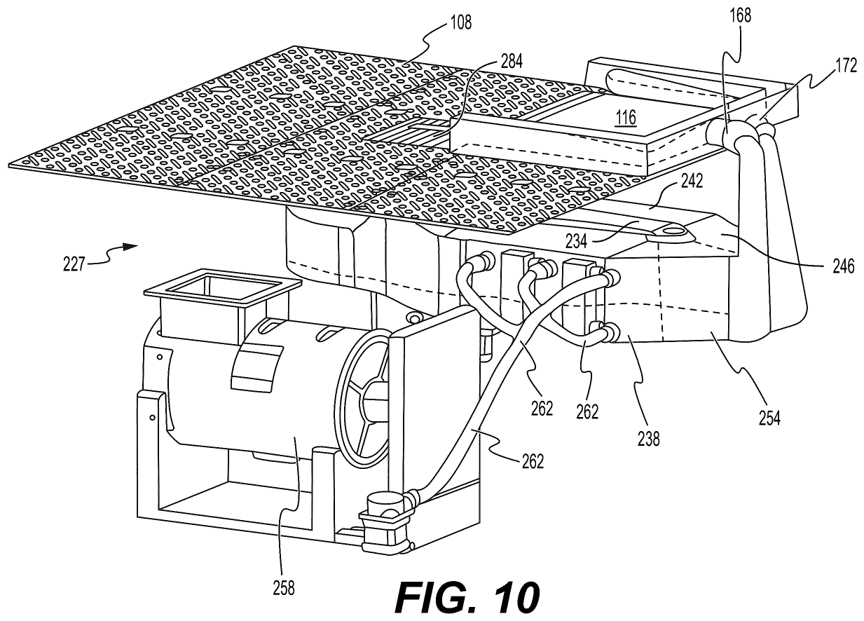

Referring now primarily to FIGS. 9, 10, and 11, the heating and cooling assemblies of an illustrative embodiment of an apparatus 227 for testing electronic components 144 will be further described. FIGS. 9 and 10 each depict perspective views of an illustrative embodiment of an apparatus 227 for testing electronic components 144, with an emphasis on the heating and cooling functions of the apparatus. As such, only portions of the apparatus 227 are depicted. For example, only the bottom portion 116 of the oven 104 is depicted in FIGS. 9 and 10. It should be understood that the top portion 112 of the oven 104 is in place, as described herein, during use of the apparatus. The same holds for other components of the apparatus 227 that are not explicitly depicted in FIGS. 9 and 10.

As described above, primarily in relation to FIGS. 4 and 5, the oven 104 is heated or cooled by blowing air through the oven 104, the air being either heated or cooled prior to entering the oven 104 to provide the desired effect. Air enters the oven 104 through the air inlet 168 and exits through the air outlet 172.

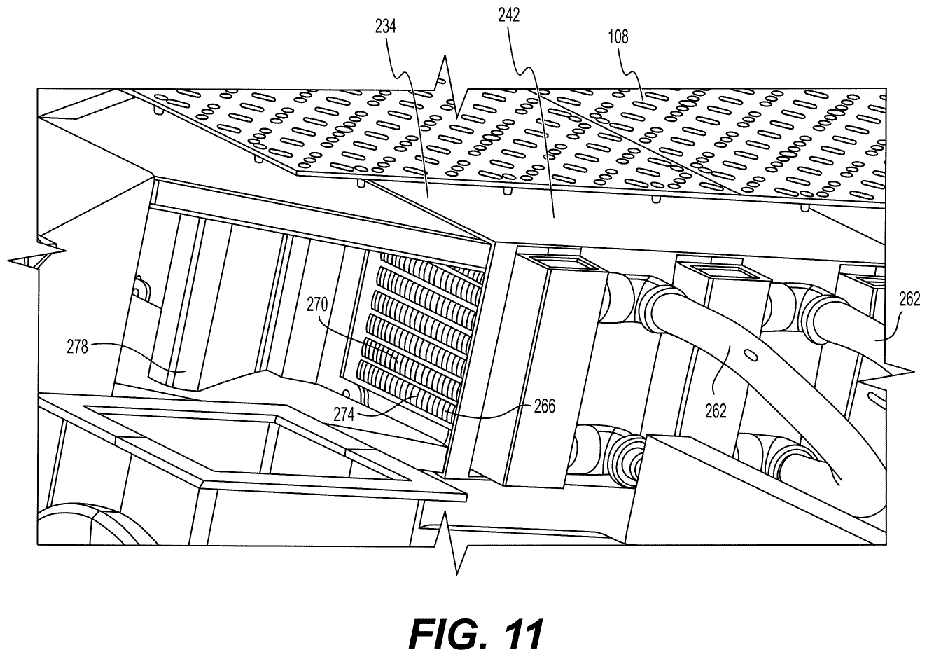

Air for the oven 104 first enters the apparatus 227 through a blower 230. The blower 230 is coupled to a heat exchanger 234. The air exiting the blower 230 is forced into the heat exchanger 234. The heat exchanger 234 is a dual heat exchanger that has a cooling side 238 and a heating side 242. Depending on which side of the heat exchanger 234 that the air is directed, the air is either heated or cooled. The air is directed between the cooling side 238 and heating side 242 by an air flow direction flap 278 described further below in connection with FIG. 11. In some embodiments, the blower 230 is a centrifugal blower that is internally insulated with 15 mm of silicone rubber sponge.

The heat exchanger 234, the blower 230, or a combination of the heat exchanger 234 and the blower 230 may be considered to be thermal conditioning system 235 that includes integrated components that work together to provide precise temperature control for testing electronic components 144. In the embodiments shown, the blower 230 is coupled to the heat exchanger 234 in a configuration that allows for selective heating or cooling of air before circulation through the oven interior 120. The dual heat exchanger design with cooling side 238 and heating side 242 enables the system to provide both heating and cooling capabilities within a single integrated unit. The air flow direction flap 278 serves as a critical control element that selectively directs air flow to either the heating side 242 or cooling side 238 of the heat exchanger 234, allowing for rapid switching between heating and cooling modes without requiring separate air handling systems. The centrifugal blower 230 with internal insulation of 15 mm silicone rubber sponge provides consistent air circulation while minimizing thermal losses and maintaining temperature stability throughout the air circulation pathways. The heating and cooling capabilities of the thermal conditioning system enable comprehensive thermal testing across a wide temperature range, allowing electronic components 144 to be subjected to both elevated and reduced temperatures as required for various testing protocols. The air circulation pathways connecting the blower 230 and heat exchanger 234 to the oven interior 120 through the air inlet 168 and air outlet 172 form a complete thermal conditioning system that maintains controlled thermal environments while preserving electrical access to the electronic components 144 through the test connectors 148.

The thermal conditioning system 235 is defined as an integrated assembly of components that work cooperatively to control the thermal environment within the oven interior 120 for testing electronic components 144. The thermal conditioning system 235 includes all components involved in heating, cooling, or circulating air or other gaseous media to achieve and maintain desired temperature conditions during component testing operations. The thermal conditioning system 235 functions as a unified system where individual components operate in coordination to provide precise thermal control capabilities. The primary components of the thermal conditioning system 235 include devices for heating air such as electric resistance heaters or other heating elements, devices for cooling air such as refrigeration systems or cryogenic coolers, devices for circulating air such as blowers or fans, and control elements for directing air flow such as the air flow direction flap 278. The thermal conditioning system 235 also includes the air circulation pathways that connect these components to the oven interior 120, including the air inlet 168 and air outlet 172 that provide fluid communication between the thermal conditioning components and the oven interior 120. The integrated nature of the thermal conditioning system 235 means that the components function together as a coordinated system rather than as independent elements, with the heating components, cooling components, air circulation components, and control elements all working in concert to achieve the desired thermal conditions for testing electronic components 144. The thermal conditioning system 235 may be configured in various ways depending on the specific testing requirements, including heating-only configurations that include only heating components and air circulation devices, cooling-only configurations that include only cooling components and air circulation devices, or combined heating and cooling configurations that include both heating and cooling capabilities within a single integrated system. The thermal conditioning system 235 maintains controlled thermal environments within the oven interior 120 while allowing electrical access to the electronic components 144 through the test connectors 148 located outside the oven interior 120, thereby enabling comprehensive thermal testing with real-time electrical monitoring and evaluation of component performance under thermal stress conditions.

The thermal conditioning system 235 is designed to heat, cool, or both heat and cool air or other fluids that are then transferred to the oven interior 120 to create controlled thermal environments for testing electronic components 144. The primary function of the thermal conditioning system 235 is to condition the air or other gaseous medium before circulation through the oven interior 120, allowing precise temperature control during component testing operations. Other devices that could heat, cool, or circulate air could be used for the thermal conditioning system 235 depending on the specific temperature requirements, testing protocols, and operational constraints of the testing application. Examples of thermal conditioning systems 235 that may be employed include electric resistance heaters with forced air circulation for heating applications, thermoelectric coolers (Peltier devices) for moderate cooling requirements, vapor compression refrigeration systems for standard cooling applications, absorption refrigeration systems for applications where waste heat is available, liquid nitrogen cooling systems for extreme low temperature testing, steam heating systems for high temperature applications, heat pump systems that can provide both heating and cooling capabilities, thermal fluid circulation systems using heated or cooled liquids, infrared heating systems for rapid heating applications, and cryogenic cooling systems using liquid helium or other cryogenic fluids for ultra-low temperature testing. The selection of the appropriate thermal conditioning system 235 depends on factors such as the required temperature range, heating and cooling rates, temperature stability requirements, energy efficiency considerations, and the specific characteristics of the electronic components 144 being tested.

The thermal conditioning system 235 may also include various air movement devices to ensure proper circulation and distribution of conditioned air throughout the oven interior 120. Fans may be incorporated at multiple locations within the air circulation pathways to enhance air flow and improve temperature uniformity. Circulation fans may be positioned within the oven interior 120 to promote mixing of heated or cooled air and eliminate temperature gradients that could result in uneven thermal conditioning of the electronic components 144. Exhaust fans may be installed at the air outlet 172 to assist in drawing conditioned air through the oven interior 120 and maintaining consistent air flow rates. Variable speed fans may be employed to allow adjustment of air circulation rates based on the specific thermal requirements of different test protocols or component types. Centrifugal fans may be used for applications requiring high static pressure to overcome flow resistance through the air circulation pathways and oven interior 120. Axial fans may be utilized for applications requiring high volume air flow with lower pressure requirements. The fans may be controlled by variable frequency drives or other speed control systems to provide precise regulation of air flow rates during thermal testing operations. Multiple fans may be operated in series or parallel configurations to achieve the desired air flow characteristics and provide redundancy for critical testing applications. The air movement devices work in conjunction with the blower 230 and heat exchanger 234 to create a comprehensive thermal conditioning system 235 that maintains controlled thermal environments while ensuring uniform temperature distribution throughout the oven interior 120. In some embodiments, the blower 230 may be omitted and other air movement devices, such as fans or pumps, may be used to circulate heated or cooled air.

The heating side 242 of the heat exchanger 234 includes a heat airflow chamber 246, shown by dashed lines, in which is disposed at least one heating element 250, shown partially by dashed lines. Since the heating elements 250 and the heat airflow chamber 246 are not visible from the exterior of the heat exchanger 234 these are shown by broken lines in FIG. 9. As air is blown through the heat airflow chamber 246 and passes the heating elements 250, the air is heated. In some embodiments, the heating elements 250 are capable of heating the air exiting the heat airflow chamber 246 to a temperature of at least 200 degrees Celsius (392 degrees Fahrenheit) or more.

The cooling side 238 of the heat exchanger includes a cooling air flow chamber 254. A heat exchanger 266 (FIG. 11) is located within the cooling air flow chamber 254. The heat exchanger 266 includes a plurality of fins 270 (FIG. 11) coupled to a coolant line 274. Cooled coolant is pumped through the coolant line 274, which results in cooling of the plurality of fins 270. As air flows over the plurality of fins 270 and the associated coolant line 274, the air is cooled.

Coolant is delivered to the coolant line 274 by a plurality of coolant lines 262. At least one of the plurality of coolant lines 262 delivers cooled coolant from a cooler 258 (FIG. 10). In the illustrative embodiment of FIGS. 9 and 10, there are three sets of fins 270 and coolant lines 274. Additional coolant lines 262 couple the internal coolant lines 274 to each other. The final coolant line 262 is used to recirculate coolant back to the cooler 258 from the final coolant line 274 in the series of coolant lines 274.

The cooler 258 may be any type of cooling device capable of providing the desired level of cooling power. In some embodiments, the cooler 258 is a compressed refrigerant type cooler. In some embodiments, the cooler 258 is a mechanical cooler such as a cryocooler. In some embodiments the cooler 258 is capable of cooling to at least −150 degrees Celsius (−302 degrees Fahrenheit). In one illustrative embodiment, the cooler is a 24V AC Free piston Stirling Cryocooler with min temperature −145 degrees C from Ningbo Juxin Ult-Low Temperature Technology Co., Ltd.

The thermal conditioning system 235 may be configured to provide heating only, cooling only, or both heating and cooling capabilities depending on the specific requirements of the testing application and the types of electronic components 144 being tested. In some embodiments, the thermal conditioning system 235 includes only heating capabilities, utilizing electric resistance heaters, infrared heating systems, or steam heating systems to provide elevated temperatures for high-temperature testing protocols. In other embodiments, the thermal conditioning system 235 includes only cooling capabilities, employing thermoelectric coolers, vapor compression refrigeration systems, liquid nitrogen cooling systems, or cryogenic cooling systems to provide reduced temperatures for low-temperature testing applications. The selection of heating-only or cooling-only configurations may be based on factors such as cost considerations, space constraints, power availability, or specific test standard requirements that only require thermal conditioning in one direction. For applications requiring comprehensive thermal testing across both elevated and reduced temperature ranges, the thermal conditioning system 235 may include both heating and cooling capabilities within a single integrated system, such as the dual heat exchanger configuration with heating side 242 and cooling side 238 described herein. The modular design of the thermal conditioning system 235 allows for customization based on the specific thermal testing requirements, enabling the system to be optimized for particular electronic component types or test protocols while maintaining the core functionality of providing controlled thermal environments with electrical access through the test connectors 148.

Referring now primarily to FIG. 11, the heat exchanger 234 includes an air flow direction flap 278 located within the heat exchanger 234 near an air flow entrance of the heat exchanger 234. The air flow direction flap 278 is variably pivotable between a heating position and a cooling position. When in the heating position, the air flow direction flap 278 is pivoted so that air flow is prevented from entering the cooling air flow chamber 254 and airflow is directed into the heat airflow chamber 246. When in the cooling position, the air flow direction flap 278 is pivoted so that air flow is prevented from entering the heating air flow chamber 246 and airflow is directed into the cooling airflow chamber 254. The position of the air flow direction flap 278 may be controlled with a servo motor. In some embodiments, the flap 278 may take an intermediate position to achieve an intermediate temperature.

In some embodiments, the air outlet 172 of the oven 104 may be fluidly coupled to an air inlet 173 of the blower 230 to allow for recirculation of heated or cooled air after the heated or cooled air passes through the oven 104.

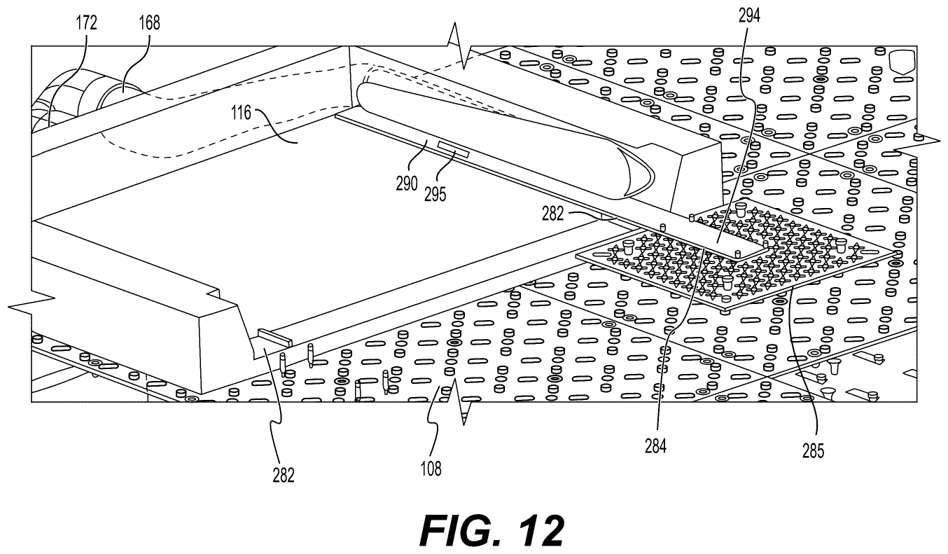

Referring now primarily to FIG. 12, an optional feature of an illustrative embodiment of the oven 104 is discussed. In FIG. 12, only the bottom portion 116 of the oven 104 is shown, for clarity. It should be understood that while the oven 104 is in use, the top portion 112 of the oven 104 is in place, such as shown in FIGS. 1 and 2.

The embodiment of the oven 104 of FIG. 12 includes two auxiliary board apertures 282. The auxiliary board apertures 282 are adjacent to the oven aperture 124 (FIG. 2). As discussed above in relation to FIGS. 1 and 2, the oven aperture 124 is an opening in the oven 104 intended for the test board 132 to pass through. The test board 132 is sandwiched between the top portion 112 and the bottom portion 116 of the oven 104.

In an analogous manner, the auxiliary board apertures 282 are intended to allow auxiliary boards 284 to be partially within the oven interior 120 and partially outside of the oven interior 120. The auxiliary board 284 may include a plurality of coupled boards, e.g., board 285. Also in an analogous manner, the auxiliary boards 284 are sandwiched between the top portion 112 and the bottom portion 116 of the oven 104 to form a seal.

For illustrative purposes, in FIG. 12, one auxiliary board aperture 282 is shown without an auxiliary board 284 in place, and the second auxiliary board aperture 282 is shown with an auxiliary board 284 in place.

The auxiliary board 284 may be used to provide additional functionality to the oven 104. The additional functionality may vary by use or purpose. For example, a monitoring device, control system, or sensors 295 or other devices may be coupled to a first end 290 of the auxiliary board 284 so that the monitoring device, control system, or sensors 295 or other device is located within the oven 104. Data from monitoring device, control system, or sensors 295 or control of other devices may be accessed by PCB connections providing electrical connections between the monitoring device, control system, or sensors 295 or other device to a second end 294 of the auxiliary board 284. For example, a test may require monitoring the rate of air flow over electronic components 144 being tested. In this case, monitoring device, control system, or sensors 295 may be a flowrate sensor or wind speed sensor coupled to the first end 290 of the auxiliary board 284 to determine the wind speed within the oven 104 during use. The data or signal collected by the monitoring device, control system, or sensors 295 can be transmitted outside of the oven 104 through PCB type connections of the auxiliary board 284 leading to the second end 294 of the auxiliary board 284.

Referring now generally to FIGS. 1-13, illustrative methods for testing electronic components 144 will be discussed. One illustrative method for testing electronic components 144 includes the steps of inserting a first portion 136 of a test board 132 into an interior 120 of a modular oven 104; heating or cooling a plurality of electronic components 144 located on the test board 132 by blowing heated or cooled air into the interior 120 of the modular oven 104 through an air inlet; and performing a component test on at least one of the electronic components 144 of the plurality of components without removing the first portion 136 of the test board 132 from the interior 120 of the modular oven 104. The component test is performed by supplying an electrical current to the electronic component 144 to be tested through a test connector 148 that is electrically coupled to the electronic component 144 to be tested.

In some embodiments of the method the test board 132 is a printed circuit board having a plurality of electronic components 144 coupled to the first portion 136 of the test board 132; a second portion 140 of the test board 132 includes a plurality of test connectors 148; the second portion 140 is not inserted into the interior 120 of the modular oven; each test connector 148 is electrically coupled to one of the plurality of electronic components 144; an air inlet is in fluid communication with the interior 120 of the modular oven 104 and is in fluid communication with a heat exchanger 234; heated or cooled air is heated or cooled in the heat exchanger 234 prior to entering the interior 120 of the modular oven 104; or the heat exchanger 234 is in fluid communication with a blower 230 for blowing the heated or cooled air into the interior 120 of the modular oven 104 through an air inlet.

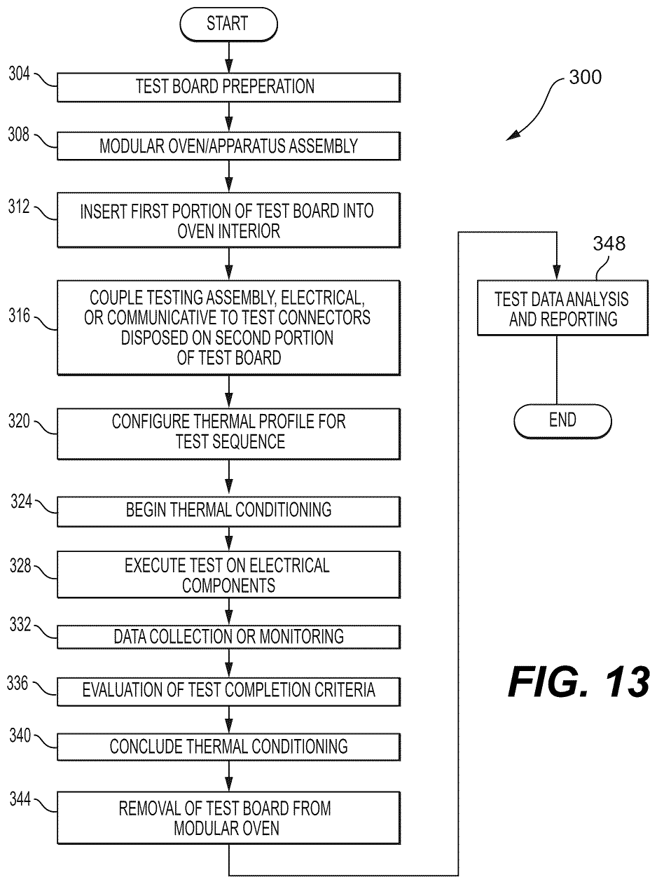

Referring now to FIG. 13, an illustrative method 300 for testing electronic components 144 using the modular oven assembly will be described in detail. The method 300 provides a systematic approach for conducting thermal testing of electronic components while maintaining electrical access for real-time monitoring and evaluation.

The method 300 begins at step 304 with preparation of the test board 132. The test board 132 is configured with electronic components 144 mounted on the first portion 136 and test connectors 148 positioned on the second portion 140. The electronic components 144 are electrically coupled to the corresponding test connectors 148 through conductive traces within the printed circuit board.

At step 308, the modular oven 104 is prepared for operation by ensuring proper assembly of the top portion 112 and bottom portion 116, verification of sealing integrity around the oven aperture 124, and confirmation that the heating and cooling systems are operational.

Step 312 involves inserting the first portion 136 of the test board 132 into the oven interior 120 through the oven aperture 124 while maintaining the second portion 140 outside the oven interior 120. The test board 132 is positioned so that it is sandwiched between the top portion 112 and bottom portion 116 to form a thermal seal around the aperture 124.

At step 316, the testing assembly 226 is connected to the test connectors 148 located on the second portion 140 of the test board 132. The testing assembly 226 provides the necessary signal generation, measurement, and control capabilities for executing comprehensive test sequences on the electronic components 144.

Step 320 involves configuring the thermal profile for the test sequence. The heat exchanger 234 is set to the desired operating mode using the air flow direction flap 278 to direct air flow to either the heating side 242 or cooling side 238. The target temperature or temperature cycling parameters are programmed into the system control.

At step 324, the thermal conditioning process begins with the blower 230 circulating conditioned air through the oven interior 120. The electronic components 144 are subjected to the specified thermal environment while remaining electrically accessible through the test connectors 148.

Step 328 involves executing electrical tests on the electronic components 144 while the components are under thermal stress. The testing assembly 226 performs the programmed test sequences, which may include functional tests, parametric measurements, stress tests, or reliability evaluations depending on the component type and test objectives.

At step 332, data collection and monitoring occurs continuously throughout the thermal testing process. Performance parameters, electrical characteristics, and thermal response data are recorded for analysis. The testing assembly 226 may log test results, measure component responses, and monitor for any failures or degradation during the thermal exposure.

Step 336 involves evaluation of test completion criteria. The system determines whether the programmed test duration has been reached, whether the required number of thermal cycles has been completed, or whether any failure criteria have been met that would terminate the test sequence. If additional testing is required, the method returns to step 324 to continue thermal conditioning and testing.

At step 340, the thermal conditioning is concluded and the oven interior 120 is allowed to return to ambient temperature. The electronic components 144 may undergo final electrical testing to evaluate any permanent changes in performance characteristics resulting from the thermal exposure.

Step 344 involves removal of the test board 132 from the modular oven 104 and disconnection of the testing assembly 226 from the test connectors 148. The electronic components 144 may be subjected to post-test analysis and evaluation.

Finally, at step 348, test data analysis and reporting is performed. The collected data is processed to evaluate component performance, reliability characteristics, and compliance with specified test standards. Test reports are generated documenting the thermal test conditions, electrical test results, and any observed component behavior during the testing process.

The method 300 described above represents one illustrative embodiment for testing electronic components 144 using the modular oven assembly. It should be understood that some steps of the method 300 may be optional depending on the specific testing requirements, component types, and test objectives. For example, step 316 involving connection of the testing assembly 226 may be optional if simpler electrical testing methods are employed, or if the electronic components 144 require only thermal exposure without active electrical testing during the thermal conditioning process. Step 320 for configuring complex thermal profiles may be simplified or omitted for applications requiring only steady-state temperature testing rather than thermal cycling. The data collection and monitoring described in step 332 may be reduced in scope for basic qualification testing or expanded significantly for detailed characterization studies.

Additionally, other steps may be included in the method 300 to accommodate specific testing requirements or component characteristics. Pre-conditioning steps may be added before step 304 to prepare electronic components 144 for testing, such as burn-in procedures, initial electrical characterization, or environmental conditioning. Calibration steps may be inserted before step 324 to verify the accuracy of temperature measurement and control systems within the oven 104. Multiple thermal cycling phases may be incorporated by repeating steps 324 through 336 with different temperature profiles or dwell times. Post-test analysis steps may be expanded beyond step 348 to include detailed failure analysis, statistical evaluation of test results, or correlation with accelerated aging models. Intermediate inspection steps may be added between thermal cycles to monitor for physical changes in the electronic components 144 such as package cracking, wire bond degradation, or other thermally induced damage. The method 300 may also include steps for testing multiple test boards 132 simultaneously using auxiliary board apertures 282, or for automated handling of test boards 132 using robotic systems associated with the workstation 100. The flexibility of the modular oven assembly allows the method 300 to be adapted and customized for a wide variety of electronic component testing applications while maintaining the core functionality of providing controlled thermal environments with electrical access for comprehensive component evaluation.

It should be appreciated that the oven 104, workstation 100, and methods for using the oven 104 and the workstation 100 herein may be used to test any type of electronic component 144 that requires testing while heated or cooled (or at room temperature) or that requires testing that involves the heating or cooling of the electronic component 144. In some embodiments, the oven 104, workstation 100, and methods for using the oven 104 and the workstation 100 are used to perform high temperature gate bias or high temperature reverse bias testing using the JESD22 A-108 standard, temperature cycle testing using the JESD22 A-104 standard, power and temperature cycle testing using the JESD22 A-105C, or pressure cook testing using the JESD22-A102-C standard, and the like, to name a few.

It should be understood that in some embodiments, robotics associated with the workstation 100 may allow for remote control of the testing over a communication network. The robotics may also allow for near real-time remote monitoring of the testing.

Although the present disclosure and its advantages have been disclosed in the context of certain illustrative, non-limiting embodiments, it should be understood that various changes, substitutions, permutations, and alterations can be made without departing from the scope of the disclosure as defined by the claims. It will be appreciated that any feature that is described in a connection to any one embodiment may also be applicable to any other embodiment.

1. An apparatus for testing electronic components comprising:
a modular oven mounted onto a worksurface of a workstation, wherein the modular oven includes a top portion, a bottom portion, an air inlet, an air outlet, and an aperture;
a heater or cooler coupled to the workstation to provide heating or cooling;
a blower fluidly coupled to the workstation;
wherein, when assembled, the top portion of the oven and the bottom portion of the oven form an oven interior;
wherein the aperture is shaped and configured to sandwich a test board between the top portion of the modular oven and the bottom portion of the modular oven;
wherein the air inlet and the air outlet provide fluid communication between the interior of the oven and an exterior of the oven; and
wherein the blower is in fluid communication with the heater or cooler and wherein the heater or cooler is in fluid communication with the air inlet, so that air that is heated or cooled by the heater or cooler may be blown by the blower into the oven interior through the air inlet and out of the oven interior through the air outlet.

2. The apparatus of claim 1, wherein the heater or cooler comprises a heat exchanger having a heating side and a cooling side.

3. The apparatus of claim 2, further comprising an air flow direction flap positioned to selectively direct air flow to either the heating side or the cooling side of the heat exchanger.
The apparatus of claim 1, wherein the heater or cooler is capable of heating and cooling.

5. The apparatus of claim 1,
wherein the test board is positioned so that a first portion of the test board is located within the oven interior and a second portion of the test board is located outside the oven interior; and
wherein electronic components to be tested are coupled to the first portion and are electrically or communicatively coupled to test connectors positioned on the second portion.

6. The apparatus of claim 1,
wherein the workstation further comprises a scaffolding support coupled to the worksurface; and
wherein the scaffolding support includes a plurality of support arms and rails configured to allow the worksurface to slide along the rails.

7. The apparatus of claim 1,
further comprising an auxiliary board aperture adjacent to the aperture, wherein the auxiliary board aperture is configured to receive an auxiliary board having at least one sensor, monitoring device, or control system coupled to a first end of the auxiliary board positioned within the oven interior; and
wherein the at least one sensor, monitoring device, or control system is electrically or communicatively coupled to at least one electrical connection located on a second end of the auxiliary board that is positioned outside the oven interior.

8. A workstation-based modular oven assembly for testing electronic components comprising:
a workstation having a work surface;
a modular oven coupled to the work surface, wherein the modular oven includes a top portion and a bottom portion that form an oven interior when assembled;
an oven aperture formed in the modular oven and configured to receive a test board having electronic components mounted on a first portion and test connectors mounted on a second portion;
wherein the test board is positioned so that the first portion is located within the oven interior and the second portion is located outside the oven interior;
a thermal conditioning system comprising a blower, a heat exchanger having a heating side and a cooling side, and air circulation pathways connecting the blower and heat exchanger to the oven interior; and
wherein the thermal conditioning system is configured to circulate heated or cooled air through the oven interior to subject the electronic components to controlled thermal conditions while maintaining electrical access to the electronic components through the test connectors.

9. The workstation-based modular oven assembly of claim 8, further comprising a testing assembly configured to connect to the test connectors and execute test sequences on the electronic components while the electronic components are subjected to thermal conditioning.

10. The workstation-based modular oven assembly of claim 8, wherein the heat exchanger includes an air flow direction flap configured to selectively direct air flow to either the heating side or the cooling side.

11. The workstation-based modular oven assembly of claim 8, wherein the workstation includes a scaffolding support having support arms and rails, wherein the work surface is configured to slide along the rails.

12. The workstation-based modular oven assembly of claim 8, further comprising additional connectors coupled to the workstation for providing power, ground, network connections, or data transfer connections to the test board.

13. The workstation-based modular oven assembly of claim 8, wherein the modular oven includes at least one auxiliary board aperture configured to receive an auxiliary board for providing sensors or additional functionality within the oven interior.

14. The workstation-based modular oven assembly of claim 8, wherein the thermal conditioning system is capable of heating air to at least 200 degrees Celsius or cooling air to at least −150 degrees Celsius.

15. A method for testing electronic components comprising the steps of:
inserting a first portion of a test board into an interior portion of modular oven, wherein the test board is a printed circuit board having a plurality of electronic components coupled to the first portion of the test board, wherein a second portion of the test board includes a plurality of test connectors and the second portion is not inserted into the interior portion of the modular oven, wherein each test connector is electrically coupled to one of the plurality of electronic components, and wherein the modular oven includes a top portion and a bottom portion and the test board is sandwiched between the top portion and the bottom portion of the modular oven;
heating or cooling the plurality of electronic components by blowing heated or cooled air into the interior of the modular oven through an air inlet, wherein the air inlet is in fluid communication with the interior of the modular oven and is in fluid communication with a heat exchanger, wherein the air is heated or cooled in the heat exchanger prior to entering the interior of the modular oven, wherein the heat exchanger is in fluid communication with a blower for blowing the heated or cooled air into the interior of the modular oven through an air inlet;
performing a component test on at least one of the components of the plurality of components without removing the first portion of the test board from the interior of the modular oven; and
wherein the component test is performed by supplying an electrical current to the component to be tested through the test connectors that are electrically coupled to the component to be tested.

16. The method of claim 15, further comprising the step of connecting a testing assembly to the test connectors, wherein the testing assembly comprises signal generation circuits, measurement circuits, or control logic for executing test sequences on the electronic components.

17. The method of claim 15, wherein the step of heating or cooling includes directing air flow to either a heating side or a cooling side of the heat exchanger using an air flow direction flap.

18. The method of claim 15, further comprising the step of thermal cycling the electronic components by alternately heating and cooling the electronic components while performing electrical tests.

19. The method of claim 15, further comprising the steps of collecting performance data during the component test and analyzing the data to evaluate component reliability under thermal stress.

20. The method of claim 15, wherein the component test includes at least one of high temperature gate bias testing, temperature cycle testing, power and temperature cycle testing, or pressure cook testing.
